(19) United States
(12) Patent Application Publication
(10) Pub. No.: US 2025/0175162 A1
(43) Pub. Date: May 29, 2025

(54) METHOD FOR CALIBRATING A PHASE MODULATOR

(71) Applicant: Infineon Technologies AG, Neubiberg (DE)

(72) Inventors: Gunther KRAUT, Egmating (DE); Thomas FASETH, Leonding (AT); Timo HAF, München (DE)

(21) Appl. No.: 18/943,088

(22) Filed: Nov. 11, 2024

(30) Foreign Application Priority Data
Nov. 24, 2023 (DE) 102023211754.1

(51) Int. Cl. H03H 11/16; H01Q 3/34

(52) U.S. Cl. CPC H03H 11/16; H01Q 3/34

(57) ABSTRACT

A method for calibrating a phase modulator includes determining a set of phase measurement values, calculating a value for each error parameter of a set of error parameters corresponding to an error model related to the phase modulator using the set of phase measurement values and at least one analytical function derived from the error model and storing for each error parameter of the set of error parameters the calculated value in a memory for setting a phase correction to the phase modulator.

### CROSS-REFERENCE TO RELATED APPLICATION

This application claims priority to Germany Patent Application No. 102023211754.1 filed on Nov. 24, 2023, the content of which is incorporated by reference herein in its entirety.

### BACKGROUND

In the field of automotive radar, mobile communication and other wireless applications, a specified number of transmit (TX) channels and receive (RX) channels are typically used to set up large numbers of virtual antenna nodes to enable digital and/or analogue beam forming, or MIMO operation. For this purpose, accurate and reliable phase shifting of the radio frequency TX signal is required to allow a stable phase relation between the TX channels. Some applications need accurate phase steps to preserve code orthogonality within one channel or from TX to TX channel (e.g., 90° steps as in the sequence 0°, 90°, 180°, 270°). Consequently, resolution and accuracy are key requirements, which for example in the application of a 77 GHz automotive radar needs to be in the range of fractions of one degree to a few degrees.

In view of the above, a need exists for a concept to provide an accurate phase shifting.

### SUMMARY

According to a first aspect is a method for calibrating a phase modulator includes determining a set of phase measurement values, wherein determining the set of phase measurement values includes the steps of: applying an RF signal to an input of the phase modulator, selecting a phase value from a predetermined set of phase values, setting the phase modulator to the selected phase value, determining a phase measurement value of the set of phase measurement values, the phase measurement value indicating a phase value measured from an RF output signal of the phase modulator set to the selected phase value, and repeating the steps of applying an RF signal to an input of the phase modulator, selecting a phase value from a predetermined set of phase values, setting the phase modulator to the selected phase value and determining a phase measurement value of the set of phase measurement values until each phase value of the set of phase values is selected.

A value for each error parameter of a set of error parameters is calculated corresponding to an error model related to the phase modulator using the set of phase measurement values and at least one analytical function derived from the error model. The calculated value is stored for each error parameter of the set of error parameters in a memory for setting a phase correction to the phase modulator.

According to a further aspect a method for operating a phase modulator includes accessing a memory to read a set of values, each of the set of values corresponding to one of a set of error parameters of an error model of the phase modulator,
calculating a phase setting value by transforming a target phase value to the phase setting value, wherein transforming the target phase value includes calculating in a non-iterative manner the phase setting value based on the target setting value and the set of values corresponding to a set of error parameters of an error model of the phase modulator.
applying an RF signal to the phase modulator and applying the calculated phase setting value to the phase modulator.

According to a further aspect a monolithic microwave integrated circuit includes a transmit path, the transmit path including a phase modulator, and a phase setting circuit coupled to the phase modulator, the phase setting circuit including a memory and a calculation element, wherein the memory is configured to store a set of values, each of the set of values corresponding to one of a set of error parameters of an error model of the phase modulator. The calculation element is configured to calculate a phase setting value by transforming a target phase value to the phase setting value, wherein transforming the target phase value includes calculating in a non-iterative manner the phase setting value based on the target setting value and the set of values corresponding to the set of error parameters of an error model of the phase modulator.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1A illustrates a circuit block diagram of a transmitter according to an example.

FIG. 1B illustrates a circuit block diagram of a phase modulator according to an example.

FIG. 1C illustrates a block diagram of an error model according to an example.

FIG. 2 illustrates a flow diagram of a method according to an example.

FIGS. 3A, 3B, 3C and 3D show examples of I-Q diagrams.

FIG. 4 shows a comparison of ideal set points and measured points in an I/Q diagram according to an example.

FIG. 5A shows a block diagram of a calculation element and FIG. 5B shows a block diagram of a compensation circuit according to an example.

FIG. 6 shows measurement results according to an example.

### DETAILED DESCRIPTION

Examples disclosed herein provide a new concept for calibrating a phase modulator which may be for example an I-Q phase modulator. The new concept is based on an error model of the phase modulator and on calculating a value for each error parameter of a set of error parameters corresponding to the error model. The new concept determines the error parameters based on setting the phase modulator to a predetermined set of phase values and measuring phase values. The concept allows to calculate estimates of the error parameters from the measured phase values by simple analytical functions in a straightforward manner. As such, the new concept distinguishes from existing solutions which are based on approximation and feedback optimization. In addition to a more accurate phase setting, the new concept disclosed herein enables shorter calibration times and allows calibration of a larger number of phase setting values. Furthermore, the power consumption and therefore heating is reduced as no lengthy and complicated calculations are needed. Furthermore, a new concept of correcting the phase errors is described. The concept uses the estimated values of the error parameters and calculates predistortion values input to the phase modulator using analytical functions. Memory for storing is reduced as only the values for the error parameters need to be stored.

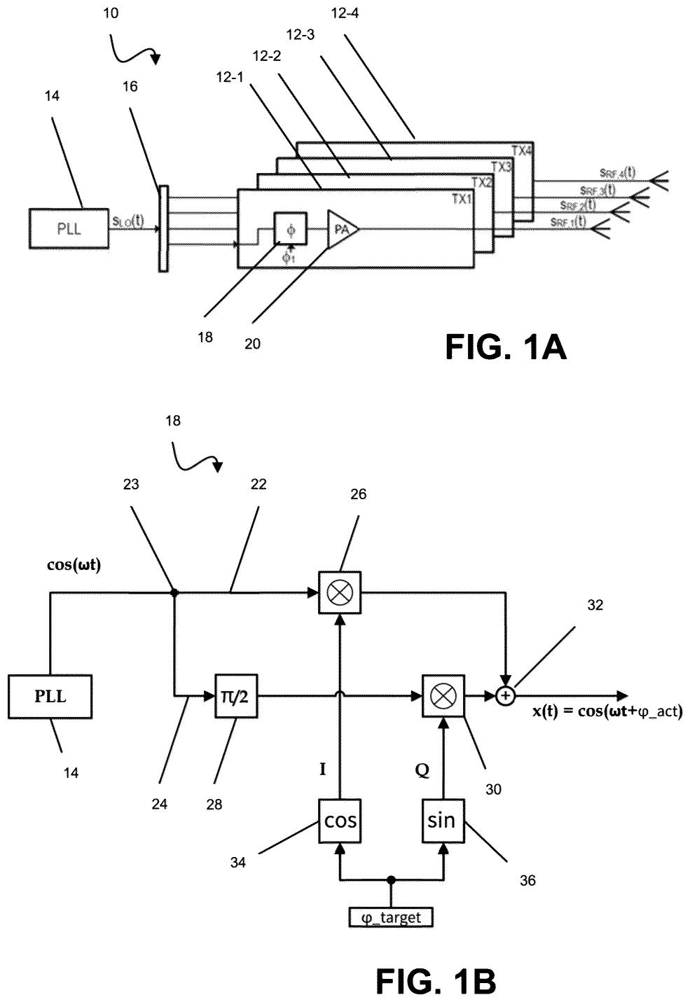

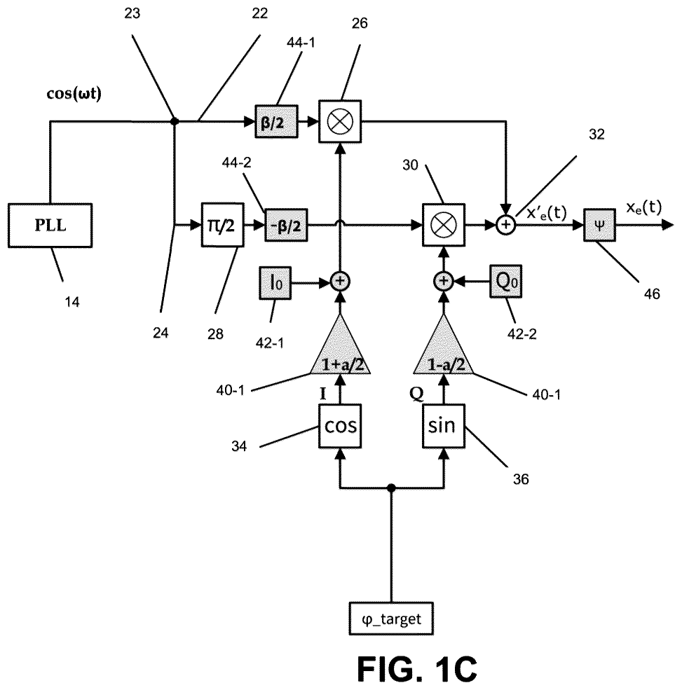

Referring now to FIG. 1A, a block diagram of a monolithic microwave integrated circuit (MMIC) 10 is shown including a plurality of transmitting channels 12-1,12-2,12-3,12-4. The MMIC 10 may for example be implemented as a transceiver device having in addition to the plurality of transmitting channels a plurality of receiving channels which are omitted for the sake of clarity. The MMIC 10 may for example be a FMCW radar device, a mobile communication device or any other wireless device. The MMIC 10 further includes a local oscillator implemented in FIG. 1 as a phase locked loop 14 which generates an LO signal S_{LO}(t) which is transferred via a splitter 16 to each input of the plurality of transmitting channels 12-1, 12-2, 12-3, 12-4. Each of the plurality of transmitting channels 12-1, 12-2, 12-3, 12-4 includes a phase modulator 18 and a power amplifier 20 to process the received LO signal and provide at an output of the respective transmitting channel an RF output signal SRF (t) which is transferred to an antenna associated with the transmitting channel. The phase of the respective transmitting channel can be controlled or digitally set to apply a defined phase shift for the transmitting channel. It is to be noted that the circuit shown in FIG. 1A may be implemented in one semiconductor chip or may use multiple semiconductor chips. For example, the phase locked loop 14 or the power amplifier 20 may be implemented on dedicated semiconductor chips.

FIG. 1B is a circuit block diagram to show the phase modulator 18 in more detail. To allow a high accuracy and stability over changing operation conditions (e.g., low phase variation over temperature and frequency range) the phase modulator 18 is implemented as an I-Q phase modulator having an I-path 22 (in-phase path) and a Q-path 24 (quadrature path). I-Q phase modulators are the most common phase modulators used in view of the above requirements. The signal from the phase locked loop 14 is split at a node 23 into an I-path signal and a Q-path signal. The I-path 22 includes a first mixer 26 (e.g., a Gilbert cell mixer) which is used to modulate the amplitude of the I-path signal. The Q-path signal 24 has a quadrature element 28 (quadrature network) which provides a phase shift of the received signal by π/2 (90 degree) to generate a Q-path signal. The Q-path has a second mixer 30 (e.g., a Gilbert cell mixer) which is used to modulate the amplitude of the Q-path signal. The amplitude modulated I-path signal and the amplitude modulated Q-path signal are combined (summed) at a combining node 32. By applying amplitude control values I and Q via circuit blocks 34 and 36 to the first mixer 26 and the second mixer 30, the phase of the input LO signal having a frequency ω_{c} can be rotated by a target phase shift angle φ=φ_{target}. The control values can be determined to be I=cos(φ), Q=sin(φ).

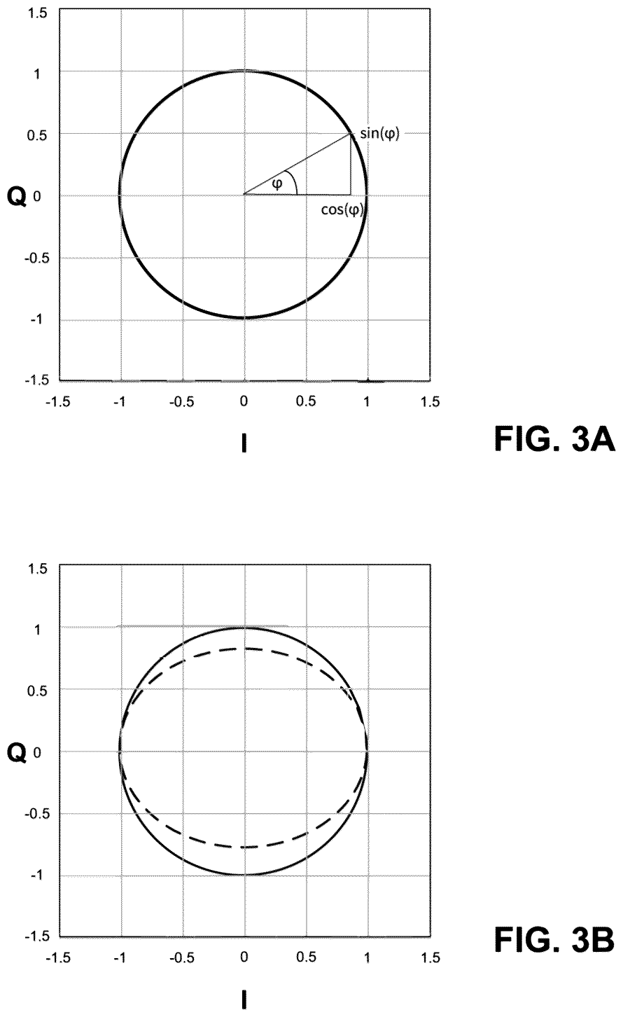

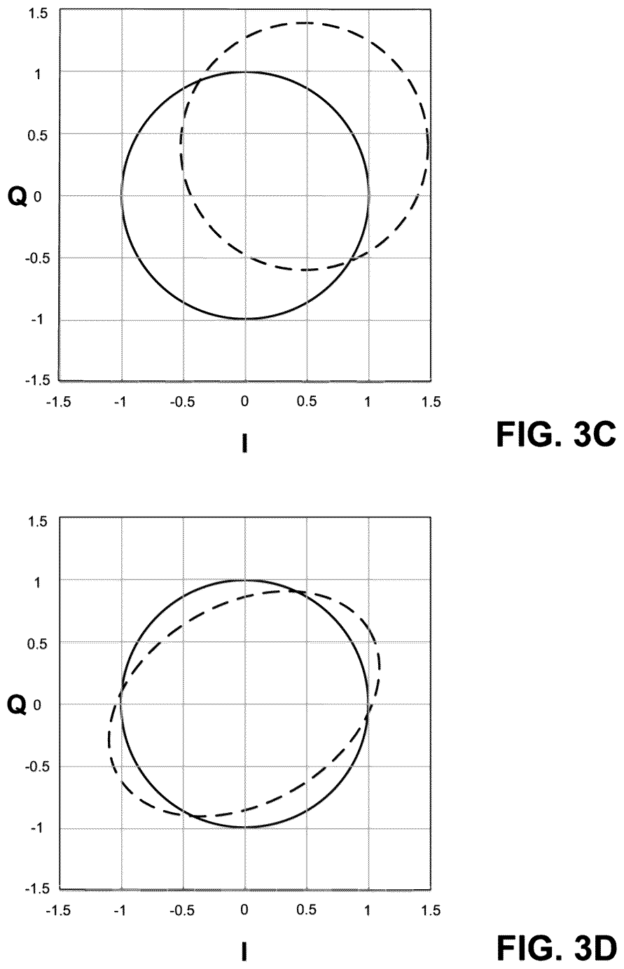

FIG. 3A shows the I-Q diagram for the ideal I-Q phase modulator in which the intended phase shift at the output of the phase modulator is obtained by setting I-Q values according to the target phase shift angle φ. Note that the I and Q values are located on a circle with unity radius. In reality, however, the circuit components of the phase modulator 18 are not ideal and suffer from impairment. This leads to errors in the phase setting if the impairments are not corrected or compensated.

Examples proposed herein provide an efficient and accurate compensation of such impairments by using an error model of the phase modulator and reducing the functional complexity of the error model to a set of analytical functions. Based on a set of measurements, values for error parameters of the error model can be determined by the set of analytical functions in a rather easy manner and compensation can be achieved by inverting the analytical functions such that the determined values of the error parameters can be input to the inverted analytical functions as variables. The compensation proposed herein is at one hand fast and uses only limited amount of memory for storing the compensation parameters.

Referring now to FIG. 1C, an example of an error model for the phase modulator 18 will be explained. The error model is based on the block diagram shown in FIG. 1C and uses a set of error parameters to describe potential errors or non-ideal behavior. A first error of the error model is the gain error 40-1 which introduces an error or imbalance between the I-path and the Q path. The gain error can be described by a first error parameter a which influences the setting for the I-path by a scaling factor 1+a/2 and influences the setting for the Q-path by a scaling factor 1−a/2. FIG. 3B shows the impact of the gain error in the I-Q diagram which leads to a distortion of the unity circle to an ellipsoidal shape.

A second error is the offset error 42-1, 42-2 which adds an offset to the setting values of the I-path and Q-path. The offset value is described by an error parameter I₀ for the I-path and an error parameter Q₀ for the Q-path. The impact of the offset error in the I-Q diagram is a shift of the unitary circle in the direction of the I-axis and/or the Q-axis depending on the values for I₀ and Q₀, see FIG. 3C.

A third error is the quadrature error 44-1, 44-2 which occurs in the quadrature element 28 and addresses imperfections in the generation of the quadrature signal, e.g., a non-orthogonal generation of the quadrature signal. The orthogonality error is represented by an error parameter β and modifies the ideal 90° phase of the Q-path signal by 90°−β/2 and the ideal 0° phase of the I-path signal by +β/2. The impact in the I-Q diagram is a modification of the unitary circle towards an ellipse having the major axis and the minor axis along two diagonal directions, see FIG. 1D.

A fourth systematic error 46 is a constant phase shift Y introduced by the phase modulator 18.

Other errors such as radio frequency (RF) cross-talk from the first mixer 26 to the second mixer 30 may be attributed to one of the described error parameters. For example, radio frequency (RF) cross-talk from an input of the first mixer 26 to its output can be attributed to the offset error although the physical mechanism is different.

Using the above model, the signal output by the phase modulator 18 excluding the systematic phase shift error can be described by

$${x}_{e}^{′} ( t ) = [ ( 1 + a / 2 ) cos φ + Io ] cos ( ω t + β / 2 ) - ( 1 - a / 2 ) sin φ + Qo ] sin ( ω t - β / 2 ) .$$

The corresponding phase φₑ′ including the phase error can be obtained according to the above-described model by

$${φ}_{e}^{′} = a tan 2 [ \begin{matrix}\begin{matrix}( 1 + a / 2 ) cos ( β / 2 ) sin φ + ( 1 + a / 2 ) sin ( β / 2 ) cos φ + \\ Io \cdot sin ( β / 2 ) + Qo \cdot cos ( β / 2 ) ,\end{matrix} \\ \begin{matrix}( 1 + a / 2 ) sin ( β / 2 ) sin φ + ( 1 + a / 2 ) cos ( β / 2 ) cos φ + \\ Io \cdot sin ( β / 2 ) + Qo \cdot cos ( β / 2 )\end{matrix}\end{matrix} ] .$$

In the above equations, a tan 2 is the 2-argument arctangent, α is the gain error, β is the quadrature error, I₀ is the I-path offset error and Q₀ is the Q-path offset error as described above.

In order to avoid an iterative solution which requires many iterations and is therefore time-consuming and difficult to implement, the examples disclosed herein utilize a non-iterative analytic approach. To this end, the above equation is expanded in a series. In one example, first and second order terms of a Taylor series of the above equation are used and combined in a unique manner to obtain a set of equations which allows determining the above error parameters. Assuming that each of the error parameters α, β, I_{α} Q₀ is much smaller than 1, products of error parameters are very small and can be considered to vanish. Furthermore, expanding cos-terms in a Taylor series and taking the first order term into account, cosine terms of an error parameter can be assumed to be 1 while sine terms of an error parameter can be assumed to be the parameter itself. In other words, cos(x)˜ 1 and sin(x)˜x where x is one of the above error parameters.

Accordingly, the phase φₑ′ is obtained in the first-order approximation as

$${φ}_{e}^{′} = a tan 2 [ \begin{matrix}( 1 - a / 2 ) sin φ + β / 2 cos φ + Qo , \\ ( 1 + a / 2 ) cos φ + B / 2 sin φ + Io\end{matrix} ] .$$

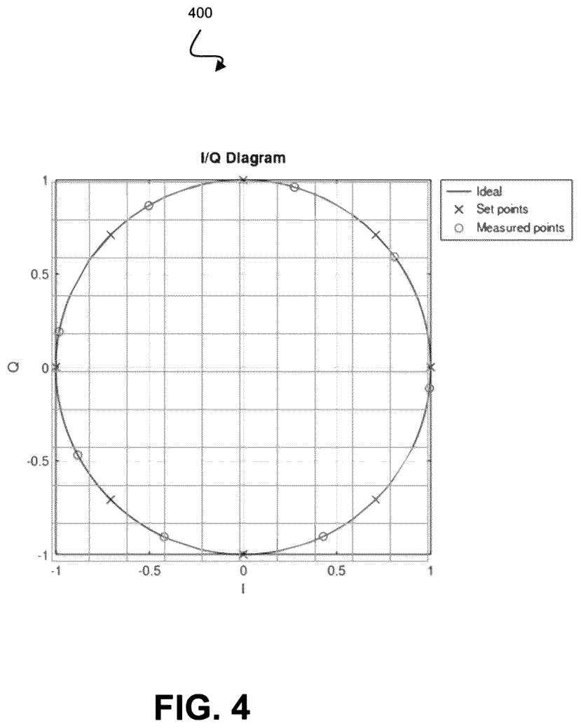

In the following, calibration measurements using the above approximation to determine the values of the error parameters will be described. A set of phase measurement values is determined based on applying a set of target phase settings to the phase modulator 18 and measuring the respective phase output of the phase modulator. FIG. 4 shows an I-Q diagram 400 indicating the respective target phase settings as crosses along the unitary circle and the measured phases for the respective target phase settings as circles.

In one example, the set of target phase setting includes the values 0, π/4, π/2, 3π/4, π, 5π/4, 3π/2 and 7π/4 (in radiant) as shown in the I-Q diagram 400 of FIG. 4. In other words, φₛ(i)=i·π/4, i=0, 1, . . . ,7, where φₛ(i) is the target phase setting for each target phase index i. For each of the target phase settings φₛ(i), an analytical expression of the resulting phase is derived by utilizing first or second order terms from the series expansion. Each analytical expression includes one or more of the error parameters as variables. By setting these analytical expressions equal to the respective actual measurement result, a set of equations is derived. Solving the set of equations, analytical expressions for the error parameters can be determined which include the measured phases for the set of target phase settings as variables.

Using the above example for the set of target phase settings, the above will be explained in more detail.

For the phase setting φ₁=0, the resulting phase φₑ₁′ is obtained

$${φ}_{e 1}^{′} = a tan 2 [ \begin{matrix}β / 2 + Qo , \\ ( 1 + a / 2 ) + Qo\end{matrix} ] .$$

Expanding a tan 2 and using the first order term results in φₑ₁′=β/2+Qo.

In a similar way, the following expressions can be obtained for each of the target phase settings as shown in Table 1.

TABLE 1
Output phase based on error model with 1. order approximation

| Target phase | Output Phase (φₑ₁) according to error |
|---|---|
| setting (φ) | model with 1. order approximation |
| 0 | $\frac{β}{2} + Qo$ |
| π/4 | $- \frac{a}{2} - \frac{Io}{\sqrt{2}} + \frac{Qo}{\sqrt{2}} + \frac{π}{4}$ |
| π/2 | $\frac{π}{2} - \frac{β}{2} - Io$ |
| 3π/4 | $\frac{a}{2} - \frac{Io}{\sqrt{2}} - \frac{Qo}{\sqrt{2}} + \frac{3 π}{4}$ |
| π | $π + \frac{β}{2} - Qo$ |
| 5π/4 | $- \frac{a}{2} + \frac{Io}{\sqrt{2}} - \frac{Qo}{\sqrt{2}} + \frac{5 π}{4}$ |
| 3π/2 | $\frac{3 π}{2} - \frac{β}{2} + Io$ |
| 7π/4 | $\frac{a}{2} + \frac{Io}{\sqrt{2}} + \frac{Qo}{\sqrt{2}} + \frac{7 π}{4}$ |

In a similar manner, analytical expressions can be derived using both, the first and second order terms of the Taylor series expansion.

This results in the following expressions shown in Table 2:

TABLE 2
Output phase based on error model with 1. and 2. order approximation

| Target phase | Output Phase (φₑ₂) according to error |
|---|---|
| setting (φ) | model with 1. and 2. order approximation |
| 0 | $\frac{β}{2} + Q o - \frac{Qo \cdot a}{2} - Io \cdot Qo$ |
| π/4 | $\text{} \begin{matrix}\frac{a β}{2} + \frac{Io \cdot β}{\sqrt{2}} - \frac{Qo \cdot β}{\sqrt{2}} + \frac{Io \cdot a}{{2}^{3 / 2}} + \frac{Qo \cdot a}{{2}^{3 / 2}} - \frac{a}{2} + \\ \frac{{Io}^{2}}{2} - \frac{{Qo}^{2}}{2} - \frac{Io}{\sqrt{2}} + \frac{Qo}{\sqrt{2}} + \frac{π}{4}\end{matrix}$ |
| π/2 | $\frac{π}{2} - \frac{β}{2} - Io - \frac{Io \cdot a}{2} + Io \cdot Qo$ |
| 3π/4 | $\text{} \begin{matrix}\frac{a β}{2} - \frac{Io \cdot β}{\sqrt{2}} - \frac{Qo \cdot β}{\sqrt{2}} + \frac{Io \cdot a}{{2}^{3 / 2}} - \frac{Qo \cdot a}{{2}^{3 / 2}} + \frac{a}{2} - \\ \frac{{Io}^{2}}{2} + \frac{{Qo}^{2}}{2} - \frac{Io}{\sqrt{2}} - \frac{Qo}{\sqrt{2}} + \frac{3 π}{4}\end{matrix}$ |
| π | $π + \frac{β}{2} - Qo + \frac{Qo \cdot a}{2} - Io \cdot Qo$ |
| 5π/4 | $\text{} \begin{matrix}\frac{a β}{2} - \frac{Io \cdot β}{\sqrt{2}} + \frac{Qo \cdot β}{\sqrt{2}} - \frac{Io \cdot a}{{2}^{3 / 2}} - \frac{Qo \cdot a}{{2}^{3 / 2}} - \frac{a}{2} + \\ \frac{{Io}^{2}}{2} - \frac{{Qo}^{2}}{2} + \frac{Io}{\sqrt{2}} - \frac{Qo}{\sqrt{2}} + \frac{5 π}{4}\end{matrix}$ |
| 3π/2 | $\frac{3 π}{2} - \frac{β}{2} + Io + \frac{Io \cdot a}{2} + Io \cdot Qo$ |
| 7π/4 | $\text{} \begin{matrix}\frac{a β}{2} + \frac{Io \cdot β}{\sqrt{2}} + \frac{Qo \cdot β}{\sqrt{2}} - \frac{Io \cdot a}{{2}^{3 / 2}} + \frac{Qo \cdot a}{{2}^{3 / 2}} + \frac{a}{2} - \\ \frac{{Io}^{2}}{2} + \frac{{Qo}^{2}}{2} + \frac{Io}{\sqrt{2}} + \frac{Qo}{\sqrt{2}} + \frac{7 π}{4}\end{matrix}$ |

Examples disclosed herein combine the analytical expressions of Tables 1 and 2 in a smart manner to obtain a set of equations that allows establishing a linear equation system which can be analytical solved to obtain the error parameters.

From the first order approximation, the following equations can be derived:

$${Δ}_{0.18} = {φ}_{e 1}^{′} ( 0 ) - {φ}_{e 1}^{′} ( π ) = 2 \cdot Qo - π \qquad ( 1 )$$

$${Δ}_{270.9} = {φ}_{e 1}^{′} ( 3 π / 2 ) - {φ}_{e 1}^{′} ( π / 2 ) = 2 \cdot Io + π \qquad ( 2 )$$

$${\sum }_{0.18} = {φ}_{e 1}^{′} ( 0 ) + {φ}_{e 1}^{′} ( π ) = β + π \qquad ( 3 )$$

$${\sum }_{270.9} = {φ}_{e 1}^{′} ( 3 π / 2 ) + {φ}_{e 1}^{′} ( π / 2 ) = 2 π - β \qquad ( 4 )$$

$${\sum }_{tot} = {\sum }_{i = 0}^{7} {φ}_{e 1}^{′} ( i \cdot π / 4 ) = 7 π \qquad ( 5 )$$

From the first and second order approximations, the following equations can be derived:

$$Δ {Δ}_{0.18} = {φ}_{e 2}^{′} ( 0 ) - {φ}_{e 2}^{′} ( π ) = 2 \cdot Qo - π - Qo \cdot a \qquad ( 6 )$$

$$Δ {Δ}_{270.9} = {φ}_{e 2}^{′} ( 3 π / 2 ) - {φ}_{e 2}^{′} ( π / 2 ) = 2 \cdot Io + π + Io \cdot a \qquad ( 7 )$$

$$\sum Δ0 = {φ}_{e 2}^{′} ( 0 ) + {φ}_{e 2}^{′} ( π ) - ( {φ}_{e 2}^{′} ( 3 π / 2 ) + {φ}_{e 2}^{′} ( π / 2 ) ) = 2 β - 4 \cdot Io \cdot Qo - π \qquad ( 8 )$$

$$\sum Δ1 = {φ}_{e 2}^{′} ( π / 4 ) + {φ}_{e 2}^{′} ( 5 π / 4 ) - ( {φ}_{e 2}^{′} ( 3 π / 4 ) + {φ}_{e 2}^{′} ( 7 π / 4 ) ) = - 2 a + 2 {Io}^{2} - 2 Q {o}^{2} - π \qquad ( 9 )$$

The error parameters can be estimated from the above equations according to the following.

The systematic phase offset is independent of the target phase setting φ(i) and can be estimated as ψₑₛₜ=(Σᵢ₌₀⁷φ_{m,o}(i)−7π)/8 where φ_{m,o}(i) is the measured output phase for each set phase φ(i) with i=1 to 8. Note that this corresponds to the mean value of the measured output phases.

Once the estimated systematic phase error ψₑₛₜ is determined, each measured phase can be corrected for the estimated systematic phase shift by introducing for each measured phase the systematic-error corrected measured phase φₘ(i) according to φₘ(i)=φ_{m,o}(i)−ψₑₛₜ.

The other error parameters can be estimated according to the following:

The baseband offset error I₀ can be estimated from equation (2) as

$${Io}_{est 1} = \frac{{φ}_{m} ( 6 ) - {φ}_{m} ( 2 ) - π}{2} .$$

In a similar manner the baseband offset error Qo can be estimated from equation (1) as

$${Qo}_{est 1} = \frac{{φ}_{m} ( 0 ) - {φ}_{m} ( 4 ) + π}{2} .$$

The orthogonality error β can be obtained from equation (8) as

$${β}_{est} = \frac{{φ}_{m} ( 0 ) + {φ}_{m} ( 4 ) - ( {φ}_{m} ( 2 ) + {φ}_{m} ( 6 ) ) + 4 {Io}_{est 1} {Qo}_{est 1} + π}{2} .$$

Note that Ioₑₛₜ₁ and Qoₑₛₜ₁ have already been estimated and can be used to determine the orthogonality error β.

Finally, the gain error a can be estimated from equation (9) as

$${a}_{est} = - \frac{{φ}_{m} ( 1 ) + {φ}_{m} ( 5 ) - ( {φ}_{m} ( 3 ) + {φ}_{m} ( 7 ) ) - 2 {Io}_{est 1}^{2} + 2 {Qo}_{est 1}^{2} + π}{2} .$$

Again, the already estimated Ioₑₛₜ₁ and Qoₑₛₜ₁ are used in order to determine the gain error a.

The above-described concept allows estimating all error parameters of the error model using simple equations which require only simple calculations steps. For example, each of the error parameters can be estimated using an analytical expression which requires for calculating a respective error parameter value a maximum of only 5 summing or subtraction operations and 3 multiplication or division-by-2ⁿ operations.

In some examples a refinement operation may be performed using already estimated error parameters. The refinement operation may increase the accuracy for some or all of the error parameters. In some examples, only a part of the error parameters may be subjected to a refinement operation.

Equations used for the refinement operation can be obtained in a similar manner using equations (1) to (9) or combinations thereof.

One example of a refinement operation for the error parameters I₀ and Q₀ will be described in the following. The refinement operation uses equation (7) to obtain for the refined I₀ error parameter a term

$${Io}_{est 2} = \frac{[ {φ}_{m} ( 6 ) - {φ}_{m} ( 2 ) - π ]}{2 - {a}_{est}}$$

and equation (6) to obtain for the refined Q₀ error parameter a term

$$Q {o}_{est 2} = \frac{[ {φ}_{m} ( 0 ) - {φ}_{m} ( 4 ) + π ]}{( 2 + {a}_{e s t} )} .$$

Using the approximation

$$\frac{1}{1 - x} \approx 1 - x$$

valid for small x, the I₀ error parameter and Q₀ error parameter can be estimated under the assumption of small values for the error parameter aₑₛₜ as

$${Io}_{est 2} = \frac{[ {φ}_{m} ( 6 ) - {φ}_{m} ( 2 ) - π ] ( 2 - {a}_{est} )}{4} and {Qo}_{est 2} = \frac{[ {φ}_{m} ( 0 ) - {φ}_{m} ( 4 ) + π ] ( 2 + {a}_{est} )}{4} .$$

Note that with the above approximation a division calculation other than division-by-2ⁿ is avoided and the estimates of the error parameters can be calculated using only summing, subtracting, multiplication and division-by-2ⁿ operations. Note that Division-by-2ⁿ operations are much easier to implement than division operations of other real or integer numbers. With the above-described processing, the errors of the phase modulator are fully modeled and the error parameter can be estimated (determined) from the output signal of the measurements with good accuracy.

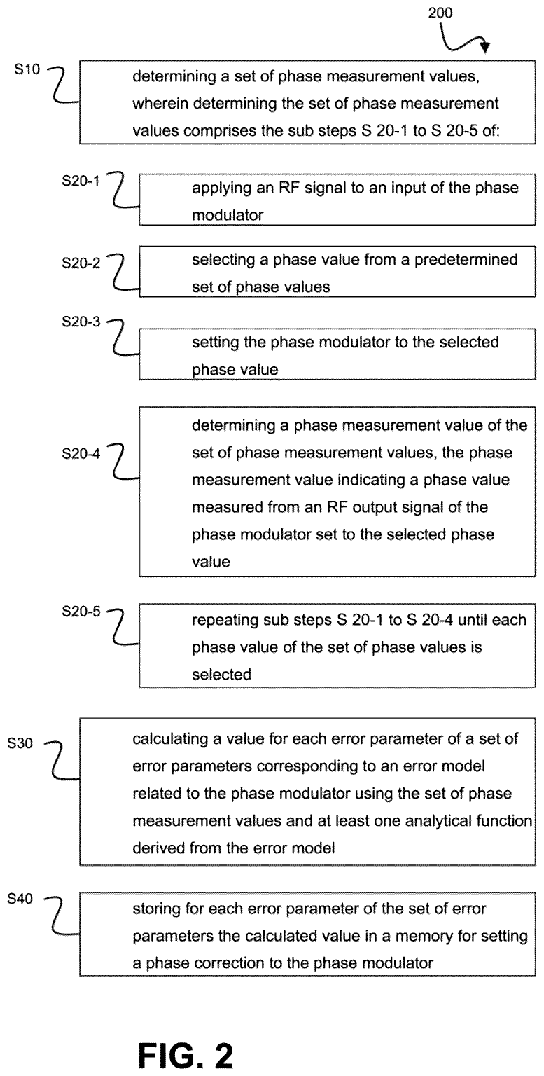

FIG. 2 shows a basic flow diagram 200 for the above-described concept of calibrating a phase modulator. The flow diagram 200 starts with a step S10 of determining a set of phase measurement values wherein determining the set of phase measurement values comprises the sub steps S20-1 to S20-5. In sub step S20-1 an RF signal is applied to an input of the phase modulator and in sub step S20-2 a phase value from a predetermined set of (target) phase values is selected. At S20-3 the phase modulator is set to the selected phase value and in S20-4 a phase measurement value of the set of phase measurement values is determined wherein the phase measurement value indicates a phase value measured from an RF output of the phase modulator set to the selected phase value. In S20-5, the sub steps S20-1 to S20-4 are repeated until each phase value of the set of phase values is selected. In S30, a value for each error parameter of a set of error parameters corresponding to an error model related to the phase modulator is calculated using the set of phase measurement values and at least one analytical function derived from the error model. At S40, each error parameter of the set of error parameters is stored in a memory for setting a phase correction to the phase modulator.

For providing phase correction for the phase modulator 18, the error model is used to provide compensation for the errors of the phase modulator 18. The compensation concept used herein makes use of the estimated values for the above-described error parameters and provides for each of the target setting phases a predistortion value for compensating the errors. To this end the estimated values for each error parameter are stored and the inverse of the analytical functions is used to obtain a predistortion value for each of the target phase settings which can be applied in digital predistortion to compensate for the errors.

A bijective function between the input phase and output phase is defined by the equation

$${φ}_{e} ( {φ}_{s} ) = a tan 2 [ \begin{matrix}( 1 - a / 2 ) cos ( β / 2 ) sin {φ}_{s} + ( 1 + a / 2 ) sin ( β / 2 ) cos {φ}_{s} + \\ Io \cdot sin ( β / 2 ) + Qo \cdot cos ( β / 2 ) , ( 1 - a / 2 ) sin ( β / 2 ) sin {φ}_{s} + \\ ( 1 + a / 2 ) cos ( β / 2 ) cos {φ}_{s} + Io \cdot sin ( β / 2 ) + Qo \cdot cos ( β / 2 )\end{matrix} ] + ψ .$$

Note that this equation maps a set target phase φₛ to an output phase de in a non-linear manner. The calculating of the compensation value is based on the inverse of φₑ(φₛ). With φₛ=φₑ(φₜ)⁻¹, the phase shifter output signal phase is φₑ(φₛ)=φₑ(φₑ(φₜ)⁻¹)=φₜ, hence obtaining the intended target phase setting φₜ as output phase at the output of the phase modulator.

Transforming the above equation into the inverse function, e.g., solving φₑ(φₛ)=φₜ for φₛ as a function of φₜ, leads to an analytical function having the target phase value φₜ and the error parameters of the error model as variables,

$${φ}_{s} ( {φ}_{t} ) = a tan 2 [ \begin{matrix}( 1 + a / 2 ) ( sin ( {φ}_{t} - ψ ) - β / 2 ) - Qo \cdot cos β ) , \\ ( 1 - a / 2 ) ( cos ( {φ}_{t} - ψ ) + β / 2 ) - Io \cdot cos β )\end{matrix} ] .$$

The upper term in the a tan 2 function represents the Q-setting Qₛ of the phase setting φₛ, the lower term represents the I setting Iₛ of the phase setting φₛ. Using approximations for small values of the error parameters, the I-setting and Q settings can be obtained as

$${I}_{s} = ( 1 - a / 2 ) ( - β / 2 \cdot sin ( {φ}_{t} - ψ ) + cos ( {φ}_{t} - ψ ) - Io )$$

$${Q}_{s} = ( 1 + a / 2 ) ( - β / 2 \cdot cos ( {φ}_{t} - ψ ) + sin ( {φ}_{t} - ψ ) - Q o )$$

The above is an analytical function which allows to obtain the predistortion values Iₛ and Qₛ for each target phase setting φₜ as a function of the error parameters. The predistortion values Iₛ and Qₛ correspond to the control values I and Q of the circuit blocks 34 and 36 values that need to be input to the mixers 26 and 30 to obtain the desired target phase setting φₜ at the output of the phase modulator 18. Estimates of the error parameters can be calculated as described above and now be used to calculate the predistortion values by

$${I}_{s} = ( 1 - {a}_{e s t} / 2 ) ( - {β}_{e s t} / 2 \cdot sin ( {φ}_{t} - {ψ}_{e s t} ) + cos ( {φ}_{t} - {ψ}_{e s t} ) - {Io}_{e s t 2} )$$

$${Q}_{s} = ( 1 + {a}_{e s t} / 2 ) ( - {β}_{e s t} / 2 \cdot cos ( {φ}_{t} - {ψ}_{e s t} ) + sin ( {φ}_{t} - {ψ}_{e s t} ) - Q {o}_{e s t 2} ) .$$

The above calculation can be realized by a calculation element implemented as a processing unit capable of simple calculation operations. In one example, the above calculations can also be realized by a calculation element implemented in pure hardware without using any programmable processing unit.

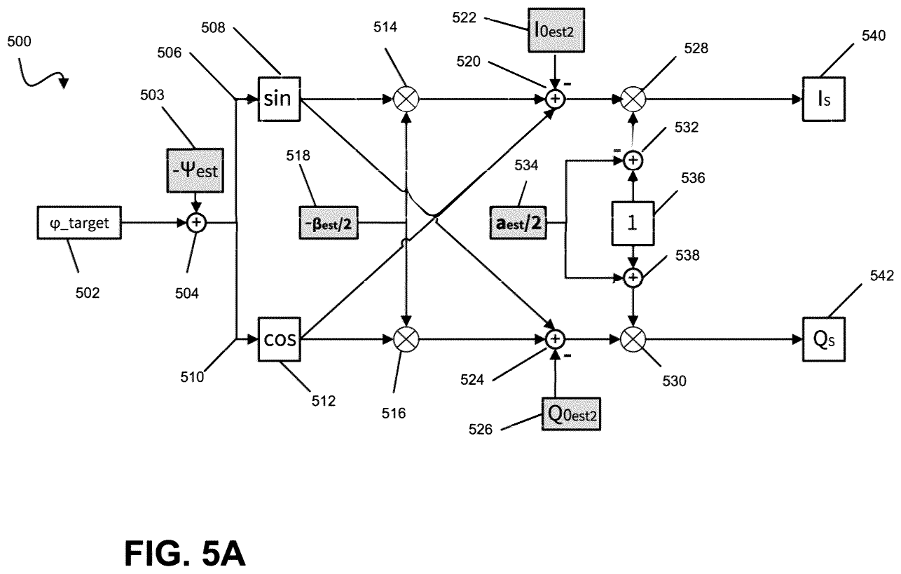

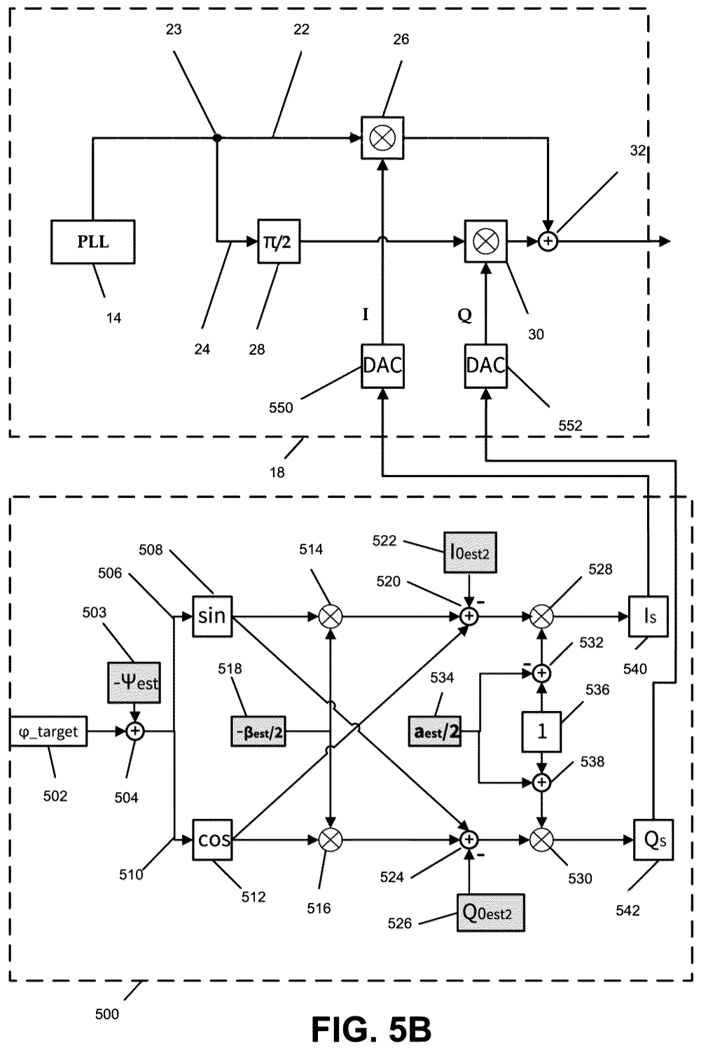

FIG. 5A shows a block diagram of a calculation element 500 implemented as a dedicated predistortion hardware circuit to calculate the predistortions values Iₛ and Qₛ. An input 502 provides the input target phase setting φₜ to a first input of adder 504. A second input of the adder 504 is connected to an input 503 providing the negative estimated systematic phase offset ψₑₛₜ to the adder 504 to calculate as an output the corrected target value φₜ−ψₑₛₜ corrected for the systematic phase offset ψₑₛₜ. The resulting corrected target value φₜ−ψₑₛₜ is provided to an I-path branch 506 and the sine value of the corrected target value φₜ−ψₑₛₜ is calculated by a block 508. Furthermore, the corrected target value φₜ−ψₑₛₜ is provided to a Q-path branch 510 and the cosine value of the corrected target value φₜ−ψₑₛₜ is calculated by a block 512. The blocks 508 and 512 may for example include a circuit implementing a coordinate rotation digital computer (CORDIC) algorithm which may use a look-up table or a look-up table and an interpolation algorithm to calculate the sine and cosine values.

The block 508 is connected to a first multiplier 514 and the block 512 is connected to a second multiplier 516. The first multiplier 514 and the second multiplier 516 are further connected to an input 518 for providing the value of −βₑₛₜ/2 as a second input to the multipliers 514 and 516, wherein βₑₛₜ is the estimated orthogonality error parameter as explained above. Accordingly, the multiplier 514 provides as output the result of −βₑₛₜ/2·sin(φₜ−ψₑₛₜ) and the multiplier 516 provides as output the result of −βₑₛₜ/2·cos(φₜ−ψₑₛₜ).

The output of the first multiplier 514 is coupled to a first input of an adder 520. A second input of the adder 520 is coupled to an output of the block 512 and a third input of the adder 520 is coupled to an input 522 to provide the negative value of the error parameter Ioₑₛₜ₂. The adder 520 sums up the input values to calculate the term −β/2·sin(φₜ−)+cos(φₜ−ψ)−Io.

In a similar manner the output of the second multiplier 516 is coupled to a first input of an adder 524. A second input of the adder 524 is coupled to an output of the block 508 and a third input of the adder 520 is coupled to an input 526 to provide the negative value of the error parameter Qoₑₛₜ₂. The adder 524 sums up the input values to calculate the term −βₑₛₜ/2·cos(φₜ−ψₑₛₜ)+sin(φₜ−ψₑₛₜ)−Qoₑₛₜ₂.

The output of the adder 520 is coupled to a first input of a third multiplier 528. A second input of the third multiplier 528 is coupled to an output of an adder 532.

A first inverting input of the adder 532 is connected to an input 534 providing the value of the error parameter αₑₛₜ/2 and a second input of the adder 532 is connected to an input 536 to provide the integer value 1. At an output the adder 532 the result of the term 1−αₑₛₜ/2 is provided to the input of the third multiplier 528. The third multiplier 528 calculates the result of the term (1−αₑₛₜ/2)(−βₑₛₜ/2·sin(φₜ−ψₑₛₜ)+cos(φₜ−ψₑₛₜ)−Ioₑₛₜ₂) and provides the calculated value to an Is-output 540 of the calculation element 500.

The output of the adder 524 is coupled to a first input of a fourth multiplier 530. A second input of the fourth multiplier 530 is coupled to an output of an adder 538.

A first input of the adder 538 is connected to the input 534 providing the value of the error parameter αₑₛₜ/2 and a second input of the adder 538 is connected to the input 536 to provide the integer value 1. At an output of the adder 538 the result of the term 1+αₑₛₜ/2 is provided to the input of the fourth multiplier 530. The fourth multiplier 530 calculates the result of the term (1+αₑₛₜ/2)(−βₑₛₜ/2·cos(φₜ−ψₑₛₜ)+sin(φₜ−ψₑₛₜ)−Qoₑₛₜ₂) and provides the calculated value to an Qs-output 542 of the calculation element 500.

It is to be noted that the above implementation is a feed-forward digital hardware circuit which does not implement any feedback loops and therefore allows calculating the predistortion values for each of the target settings at high speed. The dedicated hardware circuit requires only a CORDIC block in addition to basic adding and multiplication operations. Thus, the calculation element 500 is capable to calculate the predistortion values with low computational effort at a high speed and low implementation effort. The target phase values φₜ can be freely selected in the interval [0, 2π]. Distinguished from existing solutions which store for each phase value of a dedicated set of phase values corresponding phase correction information and optionally uses interpolation, the above concept requires to store only the values of the estimates for the error parameters which are in the above example ψₑₛₜ, ψₑₛₜ, βₑₛₜ, Ioₑₛₜ, Qoₑₛₜ. Memory can therefore be reduced while accuracy is increased. No interpolation is needed to obtain accurate phase values.

FIG. 5B shows how the calculation element 500 is coupled to the phase modulator 18 to provide predistortion for the phase modulator 18. The Is-output 540 is coupled to an input of a first digital-to-analog converter 550. The first digital-to-analog converter 550 converts the digital value received from the Is-output 540 in an analog signal which is provided to the first mixer 26 in the I-path 22 to control the gain of the first mixer 26. The Qs-output 542 is coupled to an input of a second digital-to-analog converter 552. The second digital-to-analog converter 552 converts the digital value received from the Qs-output 540 in an analog signal which is provided to the second mixer 30 in the Q-path 24 to control the gain of the second mixer 30.

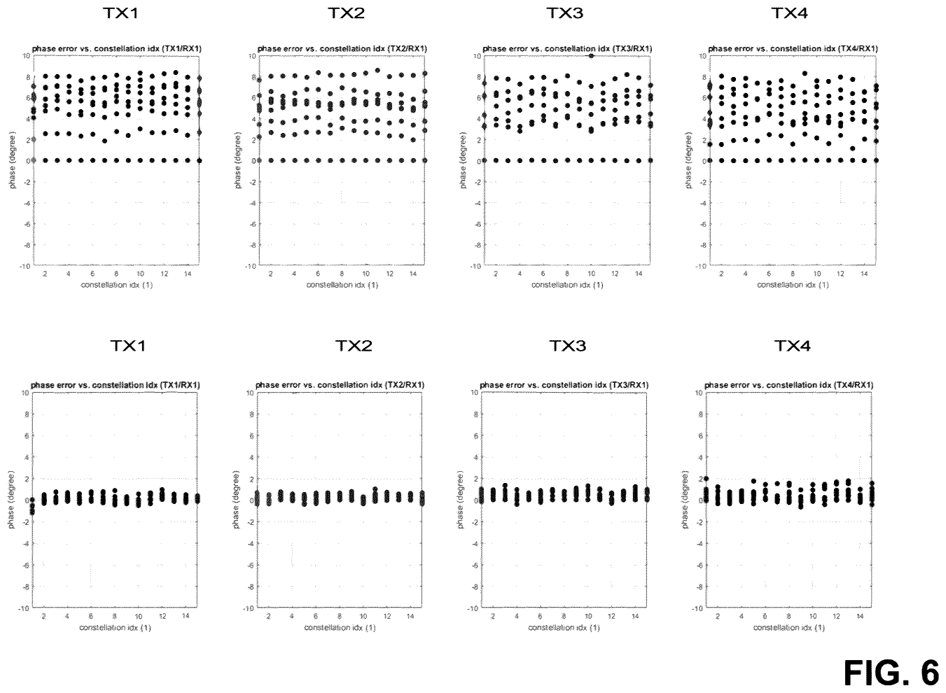

To verify the described concept, a series of measurements has been performed. FIG. 6 shows measurement results for a multiplicity of semiconductor chips of the same type each having four transmitting channels Tx1, Tx2, Tx3, Tx4. The phases have been measured using a receive channel Rx1 of each semiconductor chip. The results are shown in FIG. 6 for 15 phase settings where each phase setting has a respective index “constellation idx”. The ordinate axis shows the deviation of the measured phase from the target phase in angular degree while the abscissa axis indicates the index of the respective phase setting. The upper four diagrams show the results for the uncalibrated phase modulator for each of the transmitting channels Tx1, Tx2, Tx3, Tx4 while the lower four diagrams show the respective results using the calibration and predistortion as described above. For reference, the target phase setting having 0 deviation is also shown.

It can be observed that the phase deviations of the uncalibrated phase modulators are distributed in a range between 0 and 10 degrees with most of them being in the range between 2 and 8 degree. Distinguished therefrom, the phase deviations according to the described concept are in a range between −2 and +2 degree with most of them being in the range between −1 and +1.

The result confirm that the above concept is capable of addressing the needs required for using phase modulators in future devices requiring a high degree of phase accuracy.

### Aspects

In addition to the above described aspects, the following aspects make use of the proposed concept and are disclosed herewith.

Aspect 1 is a method for calibrating a phase modulator comprising: determining a set of phase measurement values, wherein determining the set of phase measurement values comprises the steps of: applying an RF signal to an input of the phase modulator, selecting a phase value from a predetermined set of phase values, setting the phase modulator to the selected phase value, determining a phase measurement value of the set of phase measurement values, the phase measurement value indicating a phase value measured from an RF output signal of the phase modulator set to the selected phase value, repeating the steps of applying an RF signal to an input of the phase modulator, selecting a phase value from a predetermined set of phase values, setting the phase modulator to the selected phase value and determining a phase measurement value of the set of phase measurement values until each phase value of the set of phase values is selected, calculating a value for each error parameter of a set of error parameters corresponding to an error model related to the phase modulator using the set of phase measurement values and at least one analytical function derived from the error model, storing for each error parameter of the set of error parameters the calculated value in a memory for setting a phase correction to the phase modulator.

Aspect 2 is the method according to Aspect 1, wherein the predetermined set of phase values comprises radiant values of 0, π/4, π/2, 3π/4, π, 5π/4, 3π/2 and 7π/4.

Aspect 3 is the method according to Aspect 1 or 2, wherein the set of error parameters comprises a mean value of the phase offsets, an in-phase baseband offset, a quadrature baseband offset, an orthogonality error and a gain mismatch, and wherein calculating a value for each error parameter of the set of error parameters of the error model comprises: calculating a mean value of the phase offsets using the plurality of phase measurements; calculating a set of corrected phase measurement values using the mean value of the phase offsets and the set of phase measurement values, calculating an in-phase baseband offset value using a first corrected phase measurement value of the set of corrected phase measurement values and a second corrected phase measurement value of the set of corrected phase measurement values, calculating a quadrature baseband offset value using a third corrected phase measurement value of the set of corrected phase measurement values and a fourth corrected phase measurement value of the set of corrected phase measurement values, calculating an orthogonality error value using the first corrected phase measurement value of the set of corrected phase measurement values, the second corrected phase measurement value of the set of corrected phase measurement values, the third corrected phase measurement value of the set of corrected phase measurement values and the fourth corrected phase measurement value of the set of corrected phase measurement values, calculating a gain mismatch error value using a fifth corrected phase measurement value of the set of corrected phase measurement values, a sixth corrected phase measurement value of the set of corrected phase measurement values, a seventh corrected phase measurement value of the set of corrected phase measurement values and an eighth corrected phase measurement value of the set of corrected phase measurement values.

Aspect 4 is the method according to Aspect 3, wherein calculating a mean value of the phase offset corresponds to calculating a mean value of the difference between a sum of each phase value in the predetermined set of phase values and the sum of each phase measurement value in the set of measured phase values, and wherein calculating the set of corrected phase measurement values comprises subtracting the mean value of the phase offset from each phase measurement value of the set of phase measurement values.

Aspect 5 is the method according to Aspect 3 or 4, wherein the first corrected phase measurement value is a subtraction of the mean value of the phase offset from a first phase measurement value of the set of phase measurement values and the second corrected phase measurement value is a subtraction of the mean value of the phase offset from a second phase measurement value of the set of phase measurement values, wherein the first phase measurement value corresponds to a first phase value of the set of predetermined phase values and the second phase measurement value corresponds to a second phase value of the set of predetermined phase values, wherein a difference between the first phase value and the second phase value is π, wherein the third corrected phase measurement value is a subtraction of the mean value of the phase offset from a third phase measurement value of the set of phase measurement values and the fourth corrected phase measurement value is a subtraction of the mean value of the phase offset from a fourth phase measurement value of the set of phase measurement values, wherein the third phase measurement value corresponds to a third phase value of the set of predetermined phase values and the fourth phase measurement value corresponds to a fourth phase value of the set of predetermined phase values, wherein a difference between the third phase value and the fourth phase value is, wherein the fifth corrected phase measurement value is a subtraction of the mean value of the phase offset from a fifth phase measurement value of the set of phase measurement values and the sixth corrected phase measurement value is a subtraction of the mean value of the phase offset from a sixth phase measurement value of the set of phase measurement values, wherein the fifth phase measurement value corresponds to a fifth phase value of the set of predetermined phase values and the sixth phase measurement value corresponds to a sixth phase value of the set of predetermined phase values, wherein a difference between the fifth phase value and the sixth phase value is π, wherein the seventh corrected phase measurement value is a subtraction of the mean value of the phase offset from a seventh phase measurement value of the set of phase measurement values and the eighth corrected phase measurement value is a subtraction of the mean value of the phase offset from an eighth phase measurement value of the set of phase measurement values, wherein the seventh phase measurement value corresponds to a seventh phase value of the set of predetermined phase values and the eighth phase measurement value corresponds to an eighth phase value of the set of predetermined phase values, wherein a difference between the seventh phase value and the eighth phase value is x.

Aspect 6 is the method according to Aspect 5 wherein the first phase value is π/2, the second phase value is 3π/2, the third phase value is 0, the fourth phase value is π, the fifth phase value is π/4, the sixth phase value is 5π/4, the seventh phase value is 3π/4, and the eighth phase value is 7π/4 and wherein calculating the in-phase baseband offset value is based on calculating

$$\frac{{φ}_{m} ( 6 ) - {φ}_{m} ( 2 ) - π}{2} ,$$

wherein φₘ(2) corresponds to the first corrected phase measurement value and φₘ(6) corresponds to the second corrected phase measurement value, and wherein calculating the quadrature baseband offset value is based on calculating

$$\frac{{φ}_{m} ( 0 ) - {φ}_{m} ( 4 ) + π}{2} ,$$

wherein φₘ(4) corresponds to the third corrected phase measurement value and φₘ(0) corresponds to the fourth corrected phase measurement value, and wherein calculating the orthogonality error value is based on calculating

$$\frac{{φ}_{m} ( 0 ) + {φ}_{m} ( 4 ) - ( {φ}_{m} ( 2 ) + {φ}_{m} ( 6 ) ) + 4 {Io}_{est} {Qo}_{est} + π}{2}$$

wherein I_{Oest} is the calculated in-phase baseband offset value and Q_{Oest} is the calculated quadrature baseband offset value and wherein calculating the gain mismatch error value is based on calculating

$$- \frac{{φ}_{m} ( 1 ) + {φ}_{m} ( 5 ) - ( {φ}_{m} ( 3 ) + {φ}_{m} ( 7 ) ) - 2 {Io}_{est}^{2} + 2 {Qo}_{est}^{2} + π}{2}$$

wherein φₘ(1) corresponds to the fifth corrected phase measurement value and φₘ(5) corresponds to the sixth corrected phase measurement value, wherein φₘ(3) corresponds to the seventh corrected phase measurement value and φₘ(7) corresponds to the eighth corrected phase measurement value.

Aspect 7 is the method according to Aspect 6, wherein calculating the in-phase baseband offset value and calculating the quadrature baseband offset value is based on refining a previously calculated in-phase baseband offset value and a previously calculated quadrature baseband offset value.

Aspect 8 is the method according to any of Aspects 1 to 7, wherein calculating a value for each error parameter of a set of error parameters comprises a non-iterative calculation of a value for at least an orthogonality error and gain mismatch error of the set of error parameters.

Aspect 9 is the method according to any of Aspects 1 to 8, wherein the RF signal is generated by a local oscillator implemented in a monolithic microwave integrated circuit, wherein determining a phase measurement value comprises comparing a phase of the RF signal with a phase of the RF output signal.

Aspect 10 is the method according to any of Aspects 1 to 9, wherein calculating a value for each of the error parameters does not include division calculations in which the divisor is different from 2ⁿ, where n is a natural number.

Aspect 11 is a method for operating a phase modulator, the method comprising: accessing a memory to read a set of values, each of the set of values corresponding to one of a set of error parameters of an error model of the phase modulator, calculating a phase setting value by transforming a target phase value to the phase setting value, wherein transforming the target phase value comprises calculating in a non-iterative manner the phase setting value based on the target setting value and the set of values corresponding to a set of error parameters of an error model of the phase modulator. applying an RF signal to the phase modulator and applying the calculated phase setting value to the phase modulator.

Aspect 12 is the method according to Aspect 11, wherein calculating the phase setting value comprises applying the target phase value and the plurality of values as variables to at least one analytical function, the at least one analytical function being derived from an error model of the I-Q modulator.

Aspect 13 is the method according to Aspect 11 or 12, wherein the set of error parameters comprises a mean phase offset, an in-phase baseband offset, a quadrature baseband offset, an orthogonality error and a gain mismatch.

Aspect 14 is the method according to Aspect 13, wherein calculating the phase setting value is based on calculating an I-signal value corresponding to (1−α/2)(−β/2·sin(φₜ−ψ)+cos(φₜ−ψ)−Io) and calculating a Q-signal value corresponding to (1+α/2)(−β/2·cos(φₜ−ψ)+sin(φₜ−ψ)−Qo), wherein a corresponds to a stored value of the gain mismatch, β corresponds to a stored value of the orthogonality error, Ψ corresponds to a stored value of the mean phase offset, Io corresponds to a stored value of the in-phase baseband offset, Qo corresponds to a stored value of the quadrature baseband offset and or corresponds to the target phase value, and wherein applying the phase setting value to the phase modulator comprises applying the I-signal value to an in-phase path of the phase modulator and applying the Q-signal value to a quadrature path of the phase modulator.

Aspect 15 is a monolithic microwave integrated circuit, the monolithic microwave integrated circuit comprising: a transmit path, the transmit path comprising a phase modulator, a phase setting circuit coupled to the phase modulator, the phase setting circuit comprising a memory and a calculation element, wherein the memory is configured to store a set of values, each of the set of values corresponding to one of a set of error parameters of an error model of the phase modulator, and wherein the calculation element is configured to calculate a phase setting value by transforming a target phase value to the phase setting value, wherein transforming the target phase value comprises calculating in a non-iterative manner the phase setting value based on the target setting value and the set of values corresponding to the set of error parameters of an error model of the phase modulator.

Aspect 16 is the monolithic microwave integrated circuit according to Aspect 15, wherein the calculation element is configured to calculated the phase setting value based on calculating the result of at least one analytical function, the at least one analytical function comprising the target phase value and the plurality of values as variables.

Aspect 17 is the monolithic microwave integrated circuit according to Aspect 15 or 16, wherein the set of error parameters comprises a mean phase offset, an in-phase baseband offset, a quadrature baseband offset, an orthogonality error and a gain mismatch.

Aspect 18 is the monolithic microwave integrated circuit according to any of Aspects 15 to 17, in which the calculation element is configured to calculate a phase setting value without using a divisional operation.

Aspect 19 is the monolithic microwave integrated circuit according to Aspect 18, wherein the calculation element is configured to calculate the phase setting value based on calculating an I-signal value corresponding to (1−α/2)(−β/2·sin(φₜ−ψ)+cos(φₜ−ψ)−I) and calculating a Q-signal value corresponding to (1+α/2)(−β/2· cos(φₜ−)+sin(φₜ−ψ)−I), wherein a corresponds to a stored value of the gain mismatch, β corresponds to a stored value of the orthogonality error, Ψ corresponds to a stored value of the mean phase offset, I corresponds to a stored value of the in-phase baseband offset, Q corresponds to a stored value of the quadrature baseband offset and φₜ corresponds to the target phase value, and wherein the phase setting circuit is configured to apply the I-signal value to an in-phase path of the phase modulator and applying the Q-signal value to a quadrature path of the phase modulator.

Aspect 20 is the monolithic microwave integrated circuit according to any of Aspects 12 to 19, wherein the calculation element is implemented as a feed-forward digital hardware circuit.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims and above aspects may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all aspects and implementations outlined in the present document are principally intended expressly to be only for explanatory purposes to help the reader in understanding the principles of the proposed methods and systems. Furthermore, all statements herein providing principles, aspects, and implementations of the implementation, as well as specific aspects thereof, are intended to encompass equivalents thereof.

1. A method for calibrating a phase modulator, the method comprising:
determining a set of phase measurement values, wherein determining the set of phase measurement values comprises:
applying an RF signal to an input of the phase modulator;
selecting a phase value from a predetermined set of phase values; and
setting the phase modulator to the selected phase value;
determining a phase measurement value of the set of phase measurement values, the phase measurement value indicating a phase value measured from an RF output signal of the phase modulator set to the selected phase value;
repeating the steps of applying an RF signal to an input of the phase modulator, selecting a phase value from a predetermined set of phase values, setting the phase modulator to the selected phase value and determining a phase measurement value of the set of phase measurement values until each phase value of the set of phase values is selected;
calculating a value for each error parameter of a set of error parameters corresponding to an error model related to the phase modulator using the set of phase measurement values and at least one analytical function derived from the error model; and
storing for each error parameter of the set of error parameters the calculated value in a memory for setting a phase correction to the phase modulator.

2. The method according to claim 1, wherein the predetermined set of phase values comprises radiant values of 0, π/4, π/2, π/4, π, 5π/4, 3π/2 and 7π/4.

3. The method according to claim 1,
wherein the set of error parameters comprises a mean value of phase offsets, an in-phase baseband offset, a quadrature baseband offset, an orthogonality error, and a gain mismatch, and
wherein calculating a value for each error parameter of the set of error parameters of the error model comprises:
calculating a mean value of the phase offsets using a plurality of phase measurements;
calculating a set of corrected phase measurement values using the mean value of the phase offsets and the set of phase measurement values;
calculating an in-phase baseband offset value using a first corrected phase measurement value of the set of corrected phase measurement values and a second corrected phase measurement value of the set of corrected phase measurement values;
calculating a quadrature baseband offset value using a third corrected phase measurement value of the set of corrected phase measurement values and a fourth corrected phase measurement value of the set of corrected phase measurement values;
calculating an orthogonality error value using the first corrected phase measurement value of the set of corrected phase measurement values, the second corrected phase measurement value of the set of corrected phase measurement values, the third corrected phase measurement value of the set of corrected phase measurement values and the fourth corrected phase measurement value of the set of corrected phase measurement values; and
calculating a gain mismatch error value using a fifth corrected phase measurement value of the set of corrected phase measurement values, a sixth corrected phase measurement value of the set of corrected phase measurement values, a seventh corrected phase measurement value of the set of corrected phase measurement values and an eighth corrected phase measurement value of the set of corrected phase measurement values.

4. The method according to claim 3, wherein calculating the mean value of the phase offsets corresponds to calculating a mean value of a difference between a sum of each phase value in the predetermined set of phase values and a sum of each phase measurement value in the set of measured phase values, and
wherein calculating the set of corrected phase measurement values comprises subtracting the mean value of the phase offsets from each phase measurement value of the set of phase measurement values.

5. The method according to claim 3,
wherein the first corrected phase measurement value is a subtraction of the mean value of the phase offsets from a first phase measurement value of the set of phase measurement values and the second corrected phase measurement value is a subtraction of the mean value of the phase offsets from a second phase measurement value of the set of phase measurement values,
wherein the first phase measurement value corresponds to a first phase value of the set of predetermined phase values and the second phase measurement value corresponds to a second phase value of the set of predetermined phase values,
wherein a difference between the first phase value and the second phase value is π,
wherein the third corrected phase measurement value is a subtraction of the mean value of the phase offsets from a third phase measurement value of the set of phase measurement values and the fourth corrected phase measurement value is a subtraction of the mean value of the phase offsets from a fourth phase measurement value of the set of phase measurement values,
wherein the third phase measurement value corresponds to a third phase value of the set of predetermined phase values and the fourth phase measurement value corresponds to a fourth phase value of the set of predetermined phase values,
wherein a difference between the third phase value and the fourth phase value is π,
wherein the fifth corrected phase measurement value is a subtraction of the mean value of the phase offsets from a fifth phase measurement value of the set of phase measurement values and the sixth corrected phase measurement value is a subtraction of the mean value of the phase offsets from a sixth phase measurement value of the set of phase measurement values,
wherein the fifth phase measurement value corresponds to a fifth phase value of the set of predetermined phase values and the sixth phase measurement value corresponds to a sixth phase value of the set of predetermined phase values,
wherein a difference between the fifth phase value and the sixth phase value is π,
wherein the seventh corrected phase measurement value is a subtraction of the mean value of the phase offsets from a seventh phase measurement value of the set of phase measurement values and the eighth corrected phase measurement value is a subtraction of the mean value of the phase offsets from an eighth phase measurement value of the set of phase measurement values,
wherein the seventh phase measurement value corresponds to a seventh phase value of the set of predetermined phase values and the eighth phase measurement value corresponds to an eighth phase value of the set of predetermined phase values, and
wherein a difference between the seventh phase value and the eighth phase value is π.

6. The method according to claim 5,
wherein the first phase value is π/2, the second phase value is 3π/2, the third phase value is 0, the fourth phase value is π, the fifth phase value is π/4, the sixth phase value is 5π/4, the seventh phase value is 3π/4, and the eighth phase value is 7π/4 and wherein calculating the in-phase baseband offset value is based on calculating
$$\frac{{φ}_{m} ( 6 ) - {φ}_{m} ( 2 ) - π}{2} ,$$
wherein φₘ(2) corresponds to the first corrected phase measurement value and φₘ(6) corresponds to the second corrected phase measurement value, and
wherein calculating the quadrature baseband offset value is based on calculating
$$\frac{{φ}_{m} ( 0 ) - {φ}_{m} ( 4 ) + π}{2} ,$$
wherein φₘ(4) corresponds to the third corrected phase measurement value and φₘ(0) corresponds to the fourth corrected phase measurement value, and
wherein calculating the orthogonality error value is based on calculating
$$\frac{{φ}_{m} ( 0 ) + {φ}_{m} ( 4 ) - ( {φ}_{m} ( 2 ) + {φ}_{m} ( 6 ) ) + 4 {Io}_{e s t} Q {o}_{e s t} + π}{2} ,$$
wherein I_{Oest} is the calculated in-phase baseband offset value and Q_{Oest} is the calculated quadrature baseband offset value,
wherein calculating the gain mismatch error value is based on calculating
$$- \frac{{φ}_{m} ( 1 ) + {φ}_{m} ( 5 ) - ( {φ}_{m} ( 3 ) + {φ}_{m} ( 7 ) ) - 2 {Io}_{est}^{2} + 2 {Qo}_{est}^{2} + π}{2} ,$$
wherein φₘ(1) corresponds to the fifth corrected phase measurement value and φₘ(5) corresponds to the sixth corrected phase measurement value, and
wherein φₘ(3) corresponds to the seventh corrected phase measurement value and φₘ(7) corresponds to the eighth corrected phase measurement value.

7. The method according to claim 6, wherein calculating the in-phase baseband offset value and calculating the quadrature baseband offset value is based on refining a previously calculated in-phase baseband offset value and a previously calculated quadrature baseband offset value.

8. The method according to claim 1, wherein calculating a value for each error parameter of a set of error parameters comprises a non-iterative calculation of a value for at least an orthogonality error and gain mismatch error of the set of error parameters.

9. The method according to claim 1,
wherein the RF signal is generated by a local oscillator implemented in a monolithic microwave integrated circuit, and
wherein determining a phase measurement value comprises comparing a phase of the RF signal with a phase of the RF output signal.

10. The method according to claim 1, wherein calculating a value for each of the error parameters does not include division calculations in which a divisor is different from 2ⁿ, where n is a natural number.

11. A method for operating a phase modulator, the method comprising:
accessing a memory to read a set of values, each of the set of values corresponding to one of a set of error parameters of an error model of the phase modulator;
calculating a phase setting value by transforming a target phase value to the phase setting value, wherein transforming the target phase value comprises calculating, in a non-iterative manner, the phase setting value based on the target setting value and the set of values corresponding to a set of error parameters of an error model of the phase modulator;
applying an RF signal to the phase modulator; and
applying the calculated phase setting value to the phase modulator.

12. The method according to claim 11, wherein calculating the phase setting value comprises applying the target phase value and the set of values as variables to at least one analytical function, the at least one analytical function being derived from an error model of the phase modulator.

13. The method according to claim 11, wherein the set of error parameters comprises a mean phase offset, an in-phase baseband offset, a quadrature baseband offset, an orthogonality error, and a gain mismatch.

14. The method according to claim 13,
wherein calculating the phase setting value is based on calculating an I-signal value corresponding to (1−α/2)(−β/2·sin(φₜ−ψ)+cos(φₜ-ψ)−I₀) and calculating a Q-signal value corresponding to (1+α/2)(−β/2· cos(φₜ−ψ)+sin(φₜ−ψ)−Qo),
wherein α corresponds to a stored value of the gain mismatch, β corresponds to a stored value of the orthogonality error, Ψ corresponds to a stored value of the mean phase offset, Io corresponds to a stored value of the in-phase baseband offset, Qo corresponds to a stored value of the quadrature baseband offset and φₜ corresponds to the target phase value, and
wherein applying the phase setting value to the phase modulator comprises applying the I-signal value to an in-phase path of the phase modulator and applying the Q-signal value to a quadrature path of the phase modulator.

15. A monolithic microwave integrated circuit, the monolithic microwave integrated circuit comprising:
a transmit path, the transmit path comprising a phase modulator; and
a phase setting circuit coupled to the phase modulator, the phase setting circuit comprising a memory and a calculation element,
wherein the memory is configured to store a set of values, each of the set of values corresponding to one of a set of error parameters of an error model of the phase modulator,
wherein the calculation element is configured to calculate a phase setting value by transforming a target phase value to the phase setting value, and
wherein transforming the target phase value comprises calculating in a non-iterative manner the phase setting value based on the target setting value and the set of values corresponding to the set of error parameters of an error model of the phase modulator.

16. The monolithic microwave integrated circuit according to claim 15, wherein the calculation element is configured to calculate the phase setting value based on calculating a result of at least one analytical function, the at least one analytical function comprising the target phase value and the set of values as variables.

17. The monolithic microwave integrated circuit according to claim 15, wherein the set of error parameters comprises a mean phase offset, an in-phase baseband offset, a quadrature baseband offset, an orthogonality error, and a gain mismatch.

18. The monolithic microwave integrated circuit according to claim 15, wherein the calculation element is configured to calculate a phase setting value without using a divisional operation in which a divisor is different from 2ⁿ, where n is a natural number.

19. The monolithic microwave integrated circuit according to claim 15,
wherein the calculation element is configured to calculate the phase setting value based on calculating an I-signal value corresponding to (1−α/2)(−β/2· sin(φₜ−ψ)+cos(φₜ−Ψ)−I) and calculating a Q-signal value corresponding to (1+α/2)(−β/2· cos(φₜ−ψ)+sin(φₜ−ψ)−I),
wherein α corresponds to a stored value of a gain mismatch, β corresponds to a stored value of an orthogonality error, Ψ corresponds to a stored value of a mean phase offset, I corresponds to a stored value of an in-phase baseband offset, Q corresponds to a stored value of a quadrature baseband offset, and φₜ corresponds to the target phase value, and
wherein the phase setting circuit is configured to apply the I-signal value to an in-phase path of the phase modulator and applying the Q-signal value to a quadrature path of the phase modulator.

20. The monolithic microwave integrated circuit according to claim 15, wherein the calculation element is implemented as a feed-forward digital hardware circuit.
